(19) United States
(12) Patent Application Publication
(10) Pub. No.: US 2004/0036632 A1
(43) Pub. Date: Feb. 26, 2004

(54) Universal display keyboard, system, and methods

(75) Inventor: Richard L. Ford, Nashua, NH (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 10/224,703

(22) Filed: Aug. 21, 2002

(51) Int. Cl. H03M 11/00; G09G 5/00

(52) U.S. Cl. 341/22; 341/23; 345/172

(57) ABSTRACT

A universal display keyboard can include a plurality of keys whose identifying indicia can be altered via electronically-alterable displays associated with the keys. In one embodiment, indicia associated with character and function keys can be controlled by the currently active application of an electronic device external to the keyboard. The keyboard can also include a plurality of user-operable mode-changing keys or elements to select state changes for the plurality of character and function keys. The keyboard can optionally include one or more built-in display windows to show the user helpful information about the keys or to provide application menu information. Various methods, as well as application of the keyboard to a keyboard system and to a data processing system, are also described.

### TECHNICAL FIELD

Embodiments of the present subject matter generally relate to a keyboard for interfacing with computers and, more particularly, to a keyboard interfacing with electronic devices.

### BACKGROUND INFORMATION

A keyboard is a type of input device having at least one key and used to communicate with any kind of electronic device or electronically controlled device, such as but not limited to a computer, cellular telephone, entertainment device, vehicle, home or industrial appliance, tool, musical instrument, toy, and the like. Generally a keyboard comprises a predetermined number of keys, each associated with a corresponding function.

The function(s) of each key of a keyboard is typically indicated by one or more indicia or characters printed on a visible surface of the key. Such character is generally permanently affixed to the key surface and is not alterable. Moreover, such character is typically customized to the particular application and/or user environment. For example, a keyboard used with a computer marketed in the United States is commonly supplied with keys bearing English characters to enter text, commands, and other user-initiated actions. A keyboard marketed in another country typically has keys bearing characters and/or command words native to that particular country. In some foreign countries, each English character on a specific key is accompanied by a corresponding native character, thus complicating the appearance of the keyboard. Furthermore, foreign languages can have a different set of alphabet characters, accents, and other characters than the English language, thus requiring a different keyboard layout in each corresponding country.

Also, special character sets may be needed in applications such as mathematical formulas and Unicode characters. Unicode is a universal encoding scheme for characters and text. A goal of Unicode is to provide character encoding for every character of every language of the world. Unicode supports a 16-bit character code, providing 65,000 possible characters. Unicode is maintained by the Unicode Consortium, Mountain View, Calif.

To accommodate applications requiring such special character sets, one of the known techniques provides a computer keyboard with a number of keys, called “function keys”, which serve different functions according to the software being used. These function keys, along with auxiliary keys such as ALT, CTRL, SHIFT, and other keys, are supported by various commands associated with their combinations according to the program being used. Therefore, computer users are required to study the operating manuals and to ask the computer for help by pressing a HELP key. This can result in the computer user taking a relatively long time to become familiar with the keys for the desired special commands, alternate alphabetic characters, or accents.

Another known technique for entering additional character sets uses the “character map” tool of the Windows® operating system from Microsoft Corporation of Redmond, Washington. However, this is generally slow and cumbersome to use.

Software such as the “Insert Symbol” command of the MS Word® word processing program from Microsoft Corporation is similar to the above-mentioned Windows® character map tool. Special tools and plug-ins are also available that allow one to enter characters that are unique to certain languages. But these are generally applicable only to a particular language and are not flexible enough to use with other languages or applications.

It is known to provide different character sets for selective display on the keys of a keyboard, as determined by an operator using a special select key, as shown in U.S. Pat. Nos. 4,855,740 and 4,897,651.

It is also known to provide a liquid crystal display (LCD) panel beneath a plurality of transparent keyboard keys, as shown in U.S. Pat. No. 5,515,045, and to display character and function indicia up through the keys to the keyboard user.

Therefore, there is a need for a universal display keyboard having a plurality of keys, such as character and function keys, whose identifying indicia can be readily altered. There is also a need for a universal keyboard having mode-changing keys, operable by the keyboard user, to readily change among a plurality of possible keyboard display modes or states. In addition, there is a need for a universal display keyboard having one or more built-in information screens or windows to provide the keyboard user with helpful information concerning the keyboard state and/or information concerning the indicia on the keys.

### BRIEF DESCRIPTION OF THE DRAWINGS

FIG. 1 is a perspective view of one embodiment of a universal keyboard of the present subject matter.

FIG. 1A illustrates an enlarged view of one particular key displaying a first indicia for a universal keyboard used to enter information in a first language.

FIG. 1B illustrates an enlarged view of one particular key displaying a second indicia for a universal keyboard used to enter information in a second language.

FIG. 2 illustrates a block diagram depicting an embodiment of a keyboard system 200, including major components of the universal keyboard shown in FIG. 1.

FIG. 3 shows an example computing system environment for implementing embodiments of the present subject matter.

### DETAILED DESCRIPTION

The following detailed description refers to the accompanying drawings that show, by way of illustration, specific embodiments in which the subject matter may be practiced. In the drawings, like numerals describe substantially similar components throughout the several views. These embodiments are described in sufficient detail to enable those skilled in the art to practice the subject matter. Other embodiments may be utilized, and structural, logical, and electrical changes may be made without departing from the scope of the present subject matter. Moreover, it is to be understood that the various embodiments of the subject matter, although different, are not necessarily mutually exclusive. For example, a particular feature, structure, or characteristic described in one embodiment may be included within other embodiments. The following detailed description is, therefore, not to be taken in a limiting sense, and the scope of the present subject matter is defined only by the appended claims, along with the full scope of equivalents to which such claims are entitled.

The present subject matter provides a multi-purpose universal keyboard that improves speed and efficiency during data entry operations. The keyboard supports a wide variety of applications and has utility in entering a wide variety of conventional and non-conventional characters. The keyboard supports applications involving foreign languages, mathematical formulas, Unicode characters, and many other such applications requiring additional character sets that are different from conventional characters. Also, the present subject matter offers a universal keyboard without the necessity of providing additional keys on the keyboard when using such applications. Further, the present subject matter provides a keyboard for use in such applications without the necessity of printing multiple characters on the key tops and/or surroundings of the keys according to the language or application desired. In addition, embodiments of the present subject matter provide a universal keyboard that is compatible with various software programs, and that can alter key indicia in accordance with the currently active program. In addition, the keyboard includes a plurality of user-operable mode-changing keys or elements to select state changes for the plurality of character and function keys. The keyboard can also include one or more display windows to show the user helpful information about the character and function keys.

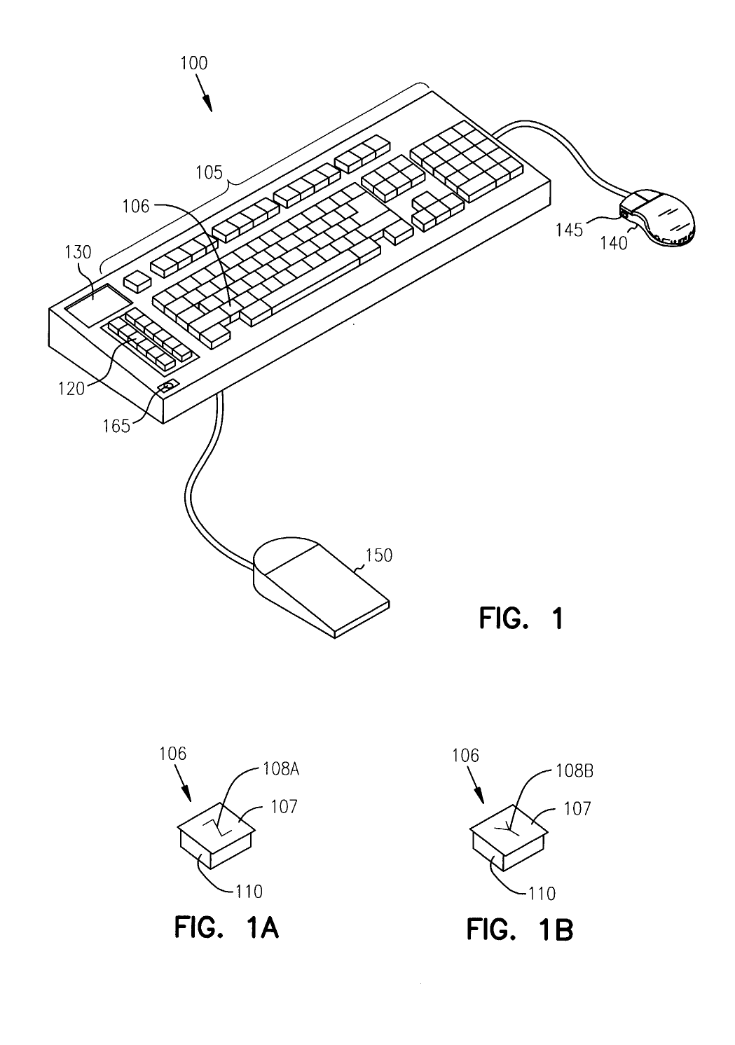

FIG. 1 is a perspective view of one embodiment of a universal keyboard 100 of the present subject matter. The universal keyboard 100 includes a plurality of character and function keys 105. Some or all of the character and function keys 105 have an associated electronically-alterable display 110 with which to indicate the associated key function to the keyboard user. The electronically-alterable display 110 can comprise any suitable type of display, such as a liquid crystal display (LCD), a light-emitting diode (LED), a light pipe, a flat panel display, and the like.

“Suitable”, as used herein, means having characteristics that are sufficient to produce the desired result(s). Suitability for the intended purpose can be determined by one of ordinary skill in the art using only routine experimentation.

As just one example, a particular key 106 has an associated electronically-alterable display 110 (refer to the enlarged views of key 106 in FIGS. 1A and 1B) of any suitable type mentioned above. Let us assume, for example, that the particular key 106 is in the lower left-hand area of universal keyboard 100 and, more specifically, that key 106 is the “Z” key on a typical “QWERTY” keyboard used in English-speaking countries.

FIG. 1A illustrates an enlarged view of key 106 displaying a first indicia 108A (namely, “Z”) for a universal keyboard 100 used to enter information in a first language, such as English. In a typical “QWERTY” keyboard used in English-speaking countries, such as the United States, a surface 107 of key 106 has a “Z” displayed thereon. It will be understood that, depending upon the type of electronically-alterable display 110, the displayed indicia may appear to visually originate from a location other than the surface 107 of key 106.

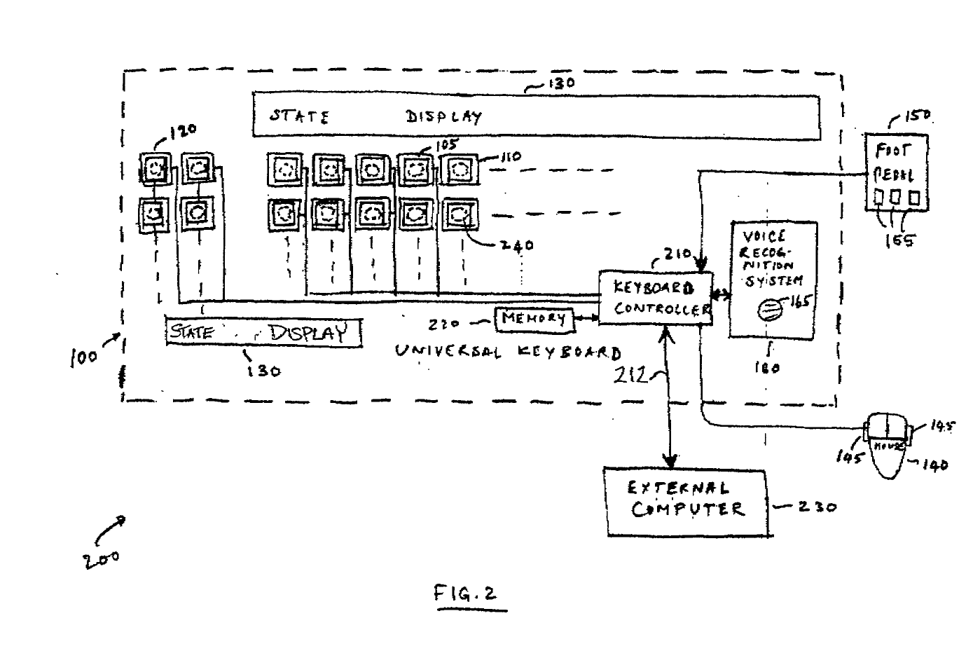

FIG. 1B illustrates an enlarged view of key 106 displaying a second indicia 108B (namely, “Y”) for a universal keyboard 100 used to enter information in a second language, such as German. For a German type “QWERTZ” keyboard, the same surface 107 of key 106 has a “Y” displayed thereon. As is well known, a German keyboard also may comprise other keys whose indicia is different from a standard American “QWERTY” keyboard. Further, many other keyboard types are known throughout the world, and each may have characters, symbols, calliphs, icons, and the like that are appropriate to the particular language. Further information concerning implementation of the electronically-alterable display will be provided below regarding the description of FIG. 2.

Those of ordinary skill in the art will understand that in the enlarged illustrations of key 106 in FIGS. 1A and 1B certain physical dimensions have been exaggerated for ease of illustration. Many different embodiments are possible. For example, the electronically-alterable display 110 could be integrated into the key 106. As another example, rather than each individual key 106 having an associated electronically-alterable display 110, a group of keys 106 could have a single large-scale electronically-alterable display providing a plurality of different characters and/or words. In another embodiment, keyboard 100 could comprise one or more keys 106 having individual electronically-alterable displays 110 and one or more groups of keys 106 each having a large-scale electronically-alterable display 110.

In the embodiment shown in FIG. 1, character and function keys 105 are laid out similarly to a conventional computer keyboard to facilitate ease of keyboarding operations without the keyboard user's having to learn a new configuration of keys.

In this example embodiment, the keyboard 100 also includes a mode-changing capability to dynamically change the mode or state of the character and function keys 105 for any desired purpose, such as to support a particular application that the keyboard user desires to use, or to support the marketing and use of the keyboard in different language regions of the world. To dynamically change the state means that the configuration of the surfaces (such as surfaces 107a and 107b) of the character and function keys 105 displaying visible patterns can be changed to facilitate the keyboarding operation of a desired application. The universal keyboard 100 may include one or more state displays 130 to display the selected state and/or to display other helpful information, such as menu information, to the keyboard user. The mode-changing capability is explained in greater detail below under the sub-heading “Mode Changing”.

The universal keyboard 100 as shown may include a pointing device such as a mouse 140, which may comprise one or more mode-changing buttons 145. In addition, the universal keyboard 100 may include a foot switch or pedal 150, and/or a voice recognition system including a built-in microphone 165 to facilitate making desired state changes. Any other type(s) of user input device could be used, such as a trackball, joy stick, touch-sensitive screen, or other user interface element(s) for entering data, commands, mode changes, and the like.

FIG. 2 illustrates a block diagram depicting an embodiment of a keyboard system 200, including major components of the universal keyboard 100 shown in FIG. 1. Keyboard system 200, in the embodiment shown, comprises universal keyboard 100 and an external electronic device such as external computer or processor 230; however, in another embodiment keyboard system 200 need not include external computer 230. Keyboard system 200 can also comprise additional user interface elements such as a mouse 140 having one or more mode-changing buttons 145, a foot pedal 150 having one or more mode-changing switches 155, and/or a voice recognition system 160 having a microphone 165.

The universal keyboard 100 includes a plurality of character and function keys 105 and can include a plurality of mode-changing keys 120. A electronically-alterable display 110, such as an LCD display, is associated with each of the character and function keys 105 and/or with the mode-changing keys 120. In one embodiment, a electronically-alterable display 110 is arranged beneath each associated key or other portion of keyboard 100; however, in other embodiments, a electronically-alterable display 110 could be arranged beside an associated key, or in any other suitable physical configuration.

The universal keyboard 100 can further comprise one or more state displays 130, a keyboard controller 210, and a memory 220.

In one embodiment, the plurality of character and function keys 105 are arranged on the keyboard 100 similarly to a conventional computer keyboard of alpha-numeric characters, to facilitate familiarity during use of the universal keyboard 100. The character and function keys 105 may be configured to have the same meaning and display as a conventional computer keyboard including alpha-numeric characters as well as various fixed-function keys (e.g. Shift, Space, Enter, etc.) and various programmable function keys (e.g. F1-F12).

In other embodiment, the character and function keys 105 can be arranged in any manner suitable for the particular type of keyboard system 200 and/or application. Embodiments of the present invention can be used with many different types of keyboard systems and applications, such as but not limited to a computer, cellular telephone, entertainment device, vehicle, home or industrial appliance, tool, musical instrument, toy, and the like.

In the embodiment depicted in FIG. 2, the character and function keys 105 are housed in rectangular or other predetermined shapes using suitable transparent or translucent materials such as glass, acrylic resin, epoxy resin, plastic, crystal, and the like. These materials are able to transmit visible characters, icons, symbols, words, and other indicia generated in a electronically-alterable display 110, such as but not limited to an LCD screen or surface which can be positioned below the keyboard 100, thereby creating indicia that resemble those on a conventional printed keyboard. The transmissive outer surfaces of the character and function keys 105 can be suitably constructed to display the above-mentioned types of indicia.

Still referring to the embodiment depicted in FIG. 2, a plurality of mode-changing keys 120 are arranged in any suitable ergonomic location on keyboard 100. The mode-changing keys 120 are configured to allow a keyboard user to make state changes dynamically in real time to the character and function keys 105 based on selected applications. The mode-changing keys 120 can be configured to work in combination with conventional auxiliary keys, such as Shift, Ctrl, Alt, and Shift Lock and/or other such keys to facilitate dynamic state changes, or the mode-changing keys 120 can operate independently of other keys. Each mode-changing key 120 can be dedicated to a particular state change or other related function.

In some embodiments, the mode-changing keys 120 may also perform functions, such as searching for information relating to state changes and providing helpful information to the keyboard user relating to state changes. The mode-changing keys 120 may also dynamically remap keys to display custom key captions based on the selected application. The applications selected for state changes can include general Unicode characters, mathematical formulas, foreign languages, and/or any other applications requiring different character sets or other indicia for the keys.

In some embodiments, the mode-changing keys 120 may also be configured to allow keyboard users to dynamically configure custom display characteristics (e.g. to alter the size and/or font of key indicia) and further to allow keyboard users to configure their own favorite mode(s) including frequently used keys. Further, the mode-changing keys 120 can be configured to work with keyboard controller 210 to keep track of frequently used keys during data entry operations. This can be used to compose favorite modes and to assign frequently used keys to a frequently used state to facilitate easier data entry operations. The electronically-alterable display 110 can be any suitable type of display including, but not limited to, a high resolution LCD display, an LED display, a flat panel display, or the like.

In some embodiments, the keyboard 100 further includes one or more state displays 130 to display selected/desired states using the mode-changing keys 120 and/or the character and function keys 105. The state displays 130 can be arranged in any suitable ergonomic location on keyboard 100. The state displays 130 can be used to display information such as a selected/desired state for the character and function keys 105, helpful information, search results, application menu(s), and/or other similar information that can facilitate easier data entry operations.

The keyboard 100 further includes electronically-alterable displays 110 associated with each of the character and function keys 105 to display visible patterns or indicia based on the selected/desired states. In one embodiment, the electronically-alterable displays 110 can be positioned below the keys to display indicia similar or identical to those on a conventional printed keyboard. In one embodiment, the electronically-alterable displays are similar to those used in small LCD televisions.

The keyboard system 200 further includes a built-in keyboard controller 210. The controller 210 can be a processor that is coupled to receive signals from character and function keys 105 and/or mode-changing keys 120. Controller 210 is coupled to memory 220.

In the embodiment shown in FIG. 2, an external computer 230 is coupled via link 212 to controller 210 of keyboard 100. Data transfer to and from the keyboard may utilize any suitable means, including wired, wireless, or optical links. In the embodiment shown in FIG. 2, external computer 230 is functionally separate from keyboard system 200 and need not perform operations that support the function of keyboard system 200. However, in other embodiments, external computer 230 could perform a variety of keyboard support operations, such as storing and retrieving character sets.

In various embodiments, controller 210 can optionally be coupled to state display(s) 130, mouse 140, foot pedal 150, and/or voice recognition system 160. In one embodiment, controller 210 is dedicated to solely to controlling the keyboard.

Controller 210 can control selected state changes, for example as instructed via user-initiated commands through any mode-changing element(s) such as mode-changing keys 120, and display application-specific visible indicia through the electronically-alterable displays 110 associated with character and function keys 105 and/or through one or more electronically-alterable state displays 130. In one embodiment, controller 210 can cause a state change in response to a command from external computer 230. For example, a particular application executing in external computer 230 can cause one or more sets of application-specific visible indicia to be displayed on the electronically-alterable displays 110. One example is discussed below in the section entitled “Mode Changing”.

Memory 220 can store any necessary data and instructions to support the functions of various embodiments of the invention. For example, memory 220 can store look-up tables including the characters, functions, and other indicia to be displayed through the character and function keys 105 and/or state display 130 based on the selected state. Memory 220 can further store necessary software to communicate with external computer 230. Such software can include protocol software in the form of machine-readable or machine-accessible instructions to convert keystroke encoded signals into Unicode or other form of binary codes necessary to communicate with the external computer 230.

Memory 220 can be a volatile memory, non-volatile memory, removable storage, non-removable storage, cache memory, random access memory (RAM), read only memory (ROM), erasable programmable read only memory (EPROM), electrically erasable programmable read only memory (EEPROM), flash memory, compact disk read only memory (CD-ROM), digital versatile disks (DVDs), optical disk storage, magnetic cassettes, magnetic tape, magnetic disk storage, memory cards, memory sticks, and any other medium capable of storing instructions and data, such as look-up tables.

As mentioned earlier, keyboard system 200 can further comprise a plurality of other mode-changing elements in addition to mode-changing keys 120. These additional mode-changing elements can comprise a mouse 140 including a plurality of mode-changing buttons 145, a foot pedal 150 including a plurality of mode-changing switches 155, a voice recognition system 160 including a built-in microphone 165 on the keyboard 100, and/or other similar user interface elements that can further aid in dynamically initiating state changes by the keyboard user. In one embodiment, the functions performed by the above-mentioned mode-changing elements are similar or identical to those performed by mode-changing keys 120.

Various alternative embodiments of keyboard 100 will now be discussed. In one embodiment, keyboard 100 is implemented as an optical keyboard that includes a back-light source (not shown) and a character/function display 240 located underneath one or more of the character and function keys 105 or groups thereof to display visible patterns through the character and function keys 105.

In another embodiment, the universal display keyboard is implemented in a manner similar to the keyboard 100 shown in FIG. 2, except that the character and function keys 105 and the mode-changing keys 120 are implemented with key-pads. Key-pads refer to touch-sensitive keys that are substantially flat, integral, and inplane with a surface of a keyboard, as opposed to keys of the type that are separate from the body of the keyboard. In addition, this embodiment of the universal display keyboard can include a back-light source and a character/function display 240 to display visible patterns or indicia through its character and function keys 105.

In another embodiment, the universal display keyboard 100 can provide expanded or multiple character sets. Desired state changes to the character and function keys 105 of an existing character set, or the expansion or replacement of an existing character set, can be dynamically initiated by the keyboard user's pressing the appropriate mode-changing keys 120 that can retrieve stored look-up tables from memory 220. Initiated state changes and application-specific visible indicia are then displayed through the character and function keys 105 using electronically-alterable displays 110 associated with each of the character and function keys 105 or with groups thereof.

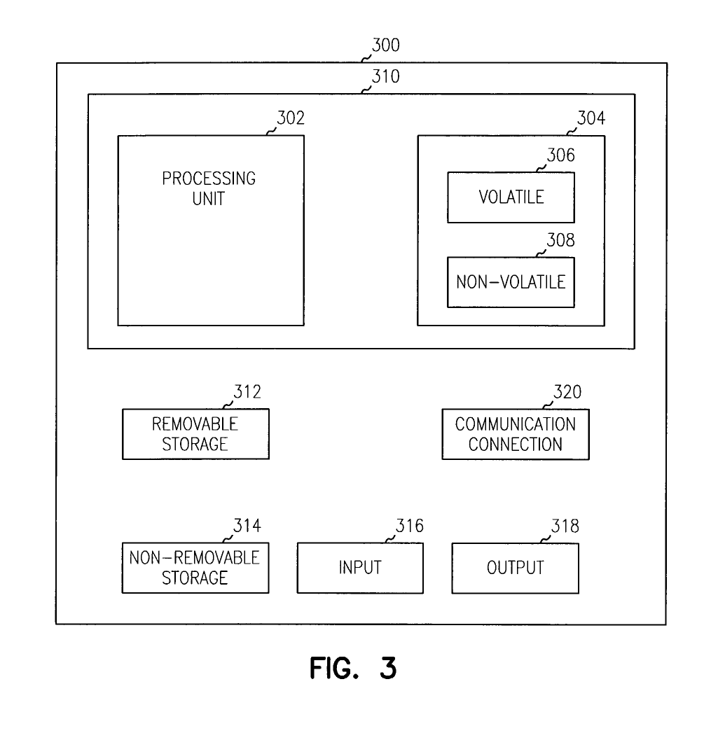

Various embodiments of the present subject matter shown in FIGS. 1 and 2 are implemented in software, which may be run in the environment shown in FIG. 3 (to be described below) or in any other suitable computing environment. The present subject matter is operable in a number of other general purpose or special purpose computing environments. Some computing environments include personal computers, general-purpose computers, server computers, hand-held devices (including but not limited to telephones and personal digital assistants of all types), laptop devices, multiprocessors, microprocessors, set-top boxes, programmable consumer electronics, network computers, minicomputers, mainframe computers, distributed computing environments, musical instruments, consumer appliances, military equipment, avionic equipment, vehicular equipment, point-of-sale terminals or equipment, gaming equipment and the like to execute the code, which is stored on a machine-accessible medium.

The present subject matter may be implemented in part or in whole as machine-executable instructions and/or information, such as program modules that are executed by a computer. Generally, program modules include routines, programs, objects, components, data structures and the like to perform particular tasks or to implement particular abstract data types. In a distributed computing environment, program modules may be located in local or remote storage devices.

FIG. 3 shows an example computing system environment for implementing embodiments of the present subject matter. FIG. 3 and the following discussion are intended to provide a brief, general description of a suitable computing environment in which certain embodiments of the inventive concepts contained herein may be implemented.

A general computing device 300 in the form of a computer 310 may include a processing unit 302, memory 304, removable storage 312, and non-removable storage 314. Memory 304 may include volatile memory 306 and non-volatile memory 308. Computer 310 may include or have access to a computing environment that includes a variety of machine-accessible media, such as volatile memory 306 and non-volatile memory 308, removable storage 312 and non-removable storage 314.

Computer storage can include any suitable memory device(s) for storing data and machine-accessible instructions, such as read only memory (ROM); random access memory (RAM); erasable programmable read only memory (EPROM); electrically erasable programmable read only memory (EEPROM); hard drive; removable media drive for handling compact disks (CDs), digital versatile disks (DVDs), diskettes, magnetic tape cartridges, memory cards, memory sticks, and the like; chemical storage; biological storage; and other types of data storage.

Computer 310 may include or have access to a computing environment that includes one or more input elements 316, one or more output elements 318, and one or more communication connections 320. The computer 310 may operate in a networked environment using a communication connection 320 to connect to one or more remote computers. A remote computer may include a personal computer, server, router, network computer, a peer device or other common network node, and the like. The communication connection may include a Local Area Network (LAN), a Wide Area Network (WAN), or other networks.

“Processor” or “processing unit”, as used herein, means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor, or any other type of processor or processing circuit. The term also includes embedded controllers, such as Generic or Programmable Logic Devices or Arrays, Application Specific Integrated Circuits, single-chip computers, smart cards, and the like.

Embodiments of the invention may be implemented in conjunction with program modules, including functions, procedures, data structures, application programs, etc. for performing tasks, or defining abstract data types or low-level hardware contexts. Program modules may be stored in memory 304 and associated storage media of the type(s) mentioned above. For example, program modules could include machine-accessible instructions and/or information for word-processing, spreadsheet, database, email, calendar, accounting, reservations, and many other types of user applications.

In one embodiment, the operation of a universal display keyboard can be emulated in software. A keyboard driver application can receive raw key strokes, regardless of which application has the input focus, and pass the processed keys (e.g. Unicode characters) to the application having the focus. The keyboard driver could display the current keyboard mapping in a screen or window (e.g. state display 130, FIG. 1) on the keyboard.

### Mode Changing

As mentioned above, embodiments of the present invention include a mode-changing capability to dynamically change the mode or state of the character and function keys 105 of the universal display keyboard 100 for any desired purpose, such as to support a particular application that the keyboard user desires to use, or to support the marketing and use of the keyboard in different language regions of the world.

To dynamically change the state, means that the configuration of the surfaces (such as surfaces 107a and 107b, FIG. 1) of the character and function keys 105 displaying visible patterns can be changed to facilitate the entry of a desired character or command for a particular application. The mode-changing capability can be implemented through any suitable user input mechanism, several of which will now be discussed.

In one embodiment, for example that illustrated in FIG. 1, one or more mode-changing keys 120 and/or groups of mode-changing keys 120 are provided. The keyboard user can change the mode or state of one or more character and function keys 105 via one or more of the mode-changing keys 120 or other mode-changing elements, such as mode-changing buttons 145 of mouse 140, foot pedal 150, and/or via voice recognition system 160 (FIG. 2).

The set of states available for any given keyboard can be determined by a finite-state machine. The set of states can be accessed in any suitable manner. For example, the set of states could be stored in non-volatile memory 308 (FIG. 3). Alternatively, it could be down-loaded from an external computer 230 (FIG. 2) or from the Internet via communication connection 320 (FIG. 3).

Activating a mode-changing operation by the keyboard user can cause a state change that could result, for example, in altered displays on the character and function keys 105, or the mode-changing operation could activate a particular function. The set of states or modes can be very large and extensible. Exploring it could be like exploring the Internet via a Web browser interface. The state display(s) 130, as well as the electronically-alterable displays 110, could provide navigation information to the keyboard user about where he or she currently is in the state space.

In another embodiment of the mode-changing capability, referring now to the embodiment shown in FIG. 2, a voice recognition system 165 can be used to capture a mode-changing command from a keyboard user. The keyboard user or application programmer could set up and employ verbal commands (e.g. any type of sound, such as a word, phrase, symbol, alpha-numeric, and the like) for common types of functions. When that verbal command is spoken, the control hardware and/or software in the keyboard 100 could recognize it and change the state of keyboard 100, so that the indicia for the functions appear on one or more of the character and function keys 105. The operation of keyboard 100 is accordingly modified, so that when a character or function key 105 is pressed, the corresponding function is performed.

Such functions can include providing an altered or substitute keyboard display, or sending a message to an external program residing in external computer 230 or in a computer or machine in a network to which keyboard 100 is coupled (e.g. through communication connection 320, FIG. 3). Voice control could be enhanced, from a reliability standpoint, by using it in conjunction with a user-actuated key, button, foot pedal, or the like (e.g. foot pedal 150, FIG. 2), to prevent the voice recognition system 160 (FIG. 2) from misinterpreting normal speech in the vicinity of microphone 165 (FIG. 2) as a voice command.

In another embodiment, the software supporting the operation of universal display keyboard 100 (FIG. 2) recognizes the functions most frequently used by the keyboard user and collects them together into a “favorites” group. The keyboard user can then use one or more of the alternative user interface mechanisms to display all of the favorites and select one for execution. In addition, the keyboard system 200 (FIG. 2) could provide a “favorites editor” to permit the keyboard user to define his or her own mapping function or other function.

In another embodiment, standard tasks can be defined, e.g. the entry of Unicode or Chinese characters. Standard state sequences could be defined. For example, depressing a “Unicode” button could first display different categories of Unicode characters on the character and/or function keys 105. The user could select the desired category, and the display would then show the Unicode characters in that category, or perhaps the characters in subcategories, if the original category has too many characters to be displayed at once. Through the use of a user-activated selection mechanism, such as mode-changing keys 105 (FIG. 2), mouse 140, foot pedal 150, voice recognition system 165, or the like, the user can select a given category or subcategory of characters, and/or switch back and forth between character sets of categories or subcategories.

In one embodiment, for example, a set of five mode-changing keys or buttons 120 could be provided for operation by the fingers and thumb of a user's hand. Each such mode-changing key 120 could select a corresponding different category of characters, so that five different character sets could easily be selected, depending upon which of the five mode-changing keys 120 were depressed.

In another embodiment, a more comprehensive mode-changing function could be implemented by the user operating a number, e.g. five, of mode-changing keys 120 in various combinations or “chords”, thus enabling the user to select a total of 2⁵=32 different character sets with only the thumb and fingers of one hand.

In yet another embodiment, operating as an editor for Extensible Markup Language (XML) or Standard Generalized Markup Language (SGML), just as an example, actuating one or more of the alternative user interface mechanisms could change the operation of keyboard 100 (FIG. 2) to a mode where legal tags are displayed on the surfaces of one or more character and function keys 105. The desired character or function key 105 could then be depressed by the keyboard user to insert the corresponding tag. The surfaces of the one or more character and function keys 105 could then change to show the different tag attributes that could be entered. When one of those is pressed, then the keyboard 100 configures for entry of the attribute value.

In a further embodiment, a plurality of mode-changing keys 120 could be provided for each hand. For example, one hand of the user could operate a first plurality of mode-changing keys 120 to chose, in effect, any one of a plurality of on-screen menus, such as drop-down menus, pop-up menus, toolbars, command lists, or the like. The user's other hand (or foot) could select from the items displayed on the on-screen menu by depressing a key (e.g. either a character or function key 105, or a mode-changing key 120) corresponding to the desired item on the on-screen menu. Providing the keyboard user with the ability to select function or command operations directly with keys, as opposed to removing the hand from its keyboard position in order to move a pointing device (such as a mouse, trackball, touch-sensitive pad, or the like) can improve the efficiency and ergonomics of the machine/user interface.

As mentioned earlier, embodiments of the present invention include a mode-changing capability to dynamically change the mode or state of the character and function keys 105 and/or of the state display(s) 130 of the universal display keyboard 100 to support one or more particular applications that the keyboard user desires to use. As just one example, assume that the user desires to use a word-processing application residing in computer 310 (FIG. 3). When the word-processing application is started, it sends unique control code to keyboard controller 210 (FIG. 2). The control code can be stored in memory 220 (FIG. 2).

The control code enables an application-specific set of indicia to be displayed on keyboard 100 (FIG. 1), such as on character and function keys 105 and/or on state displays 130. In addition, the control code enables the mode, state, and/or function of keys 105 and/or of state displays 130 to change dynamically in response to user-initiated actions.

Still referring to an example wherein the keyboard user is using a word-processing application, in a nominal operating mode a group of alpha-numeric entry keys 105 of keyboard 100 (FIG. 1) can display lower-case characters. When a shift key is depressed, the alpha-numeric entry keys 105 can display upper-case characters. If the word-processing application has a language-specifying option, e.g. if modem Greek has been selected as the applicable language by the user of keyboard 100, a group of alpha-numeric entry keys 105 of keyboard 100 will display lower-case or upper-case Greek letters, depending upon whether the shift key is depressed. Also, any information being displayed on state display 130 will be displayed in the Greek language. That is, the indicia displayed on keys 105 and/or on state display(s) 130 are controlled by the active application.

When a control key (e.g. the “Control” key on a conventional computer keyboard) is depressed, the keys 105 may display indicia corresponding to application functions associated with the keys 105. These functions can include functions that are unique to the word-processing application (e.g. an “indent” function) as well as functions that are common to several applications (e.g. “copy”, “cut”, and “insert” functions). Thus if the active application is from the Microsoft Office™ suite of applications, when the “Control” key is depressed, the “C” key can display a “copy” icon, the “X” key can display a “cut” icon, and the “V” key can display a “insert” icon. Concurrently, similar information could be displayed on a state display 130.

If the active application is WordPerfect™ from Corel Corp., when the “Control” key is depressed, the “F7” function key can display an “indent” icon, and corresponding information can concurrently be displayed on a state display 130.

The foregoing are merely a few examples of how the active application can dynamically control the indicia displayed by the keys 105 and/or on a state display 130 of keyboard 100. Many other examples are possible within the scope of various embodiments of the invention.

As shown herein, the present invention can be implemented in a number of different embodiments, including a keyboard, a keyboard system, a data processing system, various methods, and an article comprising a machine-accessible medium having associated instructions. Other embodiments will be readily apparent to those of ordinary skill in the art. The hardware elements, algorithms, and sequence of operations can all be varied to suit particular requirements.

FIGS. 1 through 3 are merely representational and are not drawn to scale. Certain proportions thereof may be exaggerated, while others may be minimized. FIGS. 1-3 are intended to illustrate various embodiments of the invention that can be understood and appropriately carried out by those of ordinary skill in the art.

It is to be understood that the above description is intended to be illustrative, and not restrictive. Many other embodiments will be apparent to those of skill in the art from the above description. The scope of the present subject matter should therefore, be determined with reference to the claims, along with the full scope of equivalents to which such claims are entitled.

It is emphasized that the Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the claims reflect, inventive subject matter lies in less than all features of a single disclosed embodiment. Thus the claims are hereby incorporated into the Detailed Description, with each claim standing on its own as a separate preferred embodiment.

What is claimed is:

1. A keyboard comprising:
a plurality of keys;
one or more electronically-alterable displays associated with the keys to display identifying indicia corresponding to such keys; and
a controller coupled to the one or more electronically-alterable displays, the controller to receive control code from an application executing on an external electronic device, the controller to control the display of the identifying indicia in accordance with the control code.

2. The keyboard recited in claim 1 and further comprising:
at least one user-operable mode-changing element to make a state change to the one or more electronically-alterable displays, the at least one user-operable mode-changing element being selected from the group consisting of a mode-changing key, a combination of two or more mode-changing keys, and a voice recognition system.

3. The keyboard recited in claim 2, wherein the combination of two or more mode-changing keys comprises 2⁵ unique combinations operable by ones of the four fingers and thumb on one hand of a keyboard user.

4. The keyboard recited in claim 1 and further comprising:
a state display to display information.

5. The keyboard recited in claim 4, wherein the state display is selected from the group consisting of a liquid crystal display, a light-emitting diode, and a flat panel display.

6. The keyboard recited in claim 4, wherein the controller is further coupled to the state display, wherein the controller is to receive control code from the application executing on the external electronic device, and wherein the controller is to control the information displayed by the state display in accordance with the control code.

7. The keyboard recited in claim 1, wherein the plurality of keys comprise character and function keys.

8. A keyboard system comprising:
a keyboard having a plurality of keys;
one or more electronically-alterable displays on the keyboard associated with the keys to provide identifying indicia corresponding to such keys;
a controller coupled to the one or more electronically-alterable displays, the controller to receive control code from an application executing on an external electronic device, the controller to control the display of the identifying indicia in accordance with the control code; and
at least one user-operable mode-changing element coupled to the keyboard to make a state change to the one or more electronically-alterable displays.

9. The keyboard system recited in claim 8 and further comprising:
a memory coupled to the controller to store machine-accessible information and data, including a plurality of key states.

10. The keyboard system recited in claim 8, wherein the mode-changing element is one of a mode-changing key, a combination of two or more mode-changing keys, at least one button on a pointing device, a foot pedal, and a voice recognition system.

11. The keyboard system recited in claim 10, wherein the combination of two or more mode-changing keys comprises 2⁵ unique combinations operable by ones of the four fingers and thumb on one hand of a keyboard user.

12. The keyboard system recited in claim 8, wherein the plurality of keys comprise character and function keys.

13. The keyboard system recited in claim 8 and further comprising:
a state display on the keyboard to display a state of the character and function keys.

14. The keyboard system recited in claim 13, wherein the controller is to receive control code from the application, and wherein the controller is to control the information displayed by the state display in accordance with the control code.

15. The keyboard system recited in claim 13, wherein the state display is selected from the group consisting of a liquid crystal display, a light-emitting diode, and a flat panel display.

16. A data processing system comprising:
a computer to execute an application; and
a keyboard system including
a keyboard having a plurality of keys;
one or more electronically-alterable displays on the keyboard associated with the keys to provide identifying indicia corresponding to such keys; and
a controller coupled to the one or more electronically-alterable displays and to the computer to receive control code, the controller to control the display of the identifying indicia in accordance with the control code.

17. The data processing system recited in claim 16, and further comprising at least one user-operable mode-changing element to make a state change to the one or more electronically-alterable displays.

18. The data processing system recited in claim 17, wherein the mode-changing element is selected from the group consisting of a mode-changing key, a combination of two or more mode-changing keys, at least one button on a pointing device, a foot pedal, and a voice recognition system.

19. The data processing system recited in claim 18, wherein the combination of two or more mode-changing keys comprises 2⁵ unique combinations operable by ones of the four fingers and thumb on one hand of a keyboard user.

20. The data processing system recited in claim 18, wherein the foot pedal comprises at least one mode switch.

21. The data processing system recited in claim 16 and further comprising:
a state display to display information.

22. The data processing system recited in claim 21, wherein the controller is to further receive control code from the application, the controller to control the information displayed by the state display in accordance with the control code.

23. The data processing system recited in claim 21, wherein the state display is selected from the group consisting of a liquid crystal display, a light-emitting diode, and a flat panel display.

24. A method comprising:
providing identifying indicia on a plurality of keys of a keyboard using one or more electronically-alterable displays physically associated with the keys; and
making a state change in the one or more electronically-alterable displays in response to control code from an executing application.

25. The method recited in claim 24 and further comprising:
making a state change in the one or more electronically-alterable displays by operating a mode-changing element selected from the group consisting of a mode-changing key, a combination of two or more mode-changing keys, at least one button on a pointing device, a foot pedal, and a voice recognition system.

26. The method recited in claim 25 wherein, in making, the combination of two or more mode-changing keys comprises 2⁵ unique combinations and such combinations are made by ones of the four fingers and thumb on one hand of a human keyboard user.

27. The method recited in claim 24 and further comprising:
displaying a state of the keys on a state display.

28. The method recited in claim 27 wherein, in displaying, the state display is selected from the group consisting of a liquid crystal display, a light-emitting diode, and a flat panel display.

29. The method recited in claim 27 and further comprising:
changing information displayed in the state display in response to an additional control code from the executing application.

30. The method of claim 24 and further comprising:
displaying one from the group consisting of a menu, a command list, and a toolbar on a state display.

31. An article comprising a machine-accessible medium having associated instructions, wherein the instructions, when accessed, result in a machine performing:
providing identifying indicia on a plurality of keys of a keyboard through one or more electronically-alterable displays physically associated with the keys; and
making a state change in the one or more electronically-alterable displays solely in response to control code from an executing application.

32. The article of claim 31 wherein the keyboard comprises a state display, and wherein the instructions, when accessed, result in the machine performing:
displaying on the state display a state of the keys.

33. The article of claim 31 wherein the keyboard comprises a state display, and wherein the instructions, when accessed, result in the machine performing:
changing information displayed in the state display in response to an additional control code from the executing application.

34. The article of claim 31 wherein the keyboard comprises a state display, and wherein the instructions, when accessed, result in the machine performing:
displaying on the state display one from the group consisting of a menu, a command list, and a toolbar.
